(19) United States
(12) Patent Application Publication
(10) Pub. No.: US 2026/0101643 A1
(43) Pub. Date: Apr. 9, 2026

(54) DISPLAY APPARATUS AND ELECTRONIC APPARATUS INCLUDING THE SAME

(71) Applicant: Samsung Display Co., Ltd., Yongin-Si (KR)

(72) Inventor: HYUNEOK SHIN, Yongin-si (KR)

(21) Appl. No.: 19/343,072

(22) Filed: Sep. 29, 2025

(30) Foreign Application Priority Data
Oct. 7, 2024 (KR) 10-2024-0135996

(51) Int. Cl. H10K 59/122; H10K 59/80

(52) U.S. Cl. CPC H10K 59/122; H10K 59/80517

(57) ABSTRACT

Provided is a display apparatus including a substrate, a pixel electrode arranged on the substrate, a pixel defining layer on the pixel electrode, the pixel defining layer having a first opening extending to a central portion of the pixel electrode, an intermediate layer on the pixel electrode and including an emission layer, a metal layer on the intermediate layer, the metal layer having a second opening extending to expose a central portion of the intermediate layer, and an opposite electrode continuously disposed on the intermediate layer and the metal layer.

### CROSS-REFERENCE TO RELATED APPLICATION

This application is based on and claims priority, under 35 USC § 119, to Korean Patent Application No. 10-2024-0135996 filed on Oct. 7, 2024 in the Korean Intellectual Property Office, the disclosure of which is incorporated by reference herein in its entirety.

### BACKGROUND

1. Field

One or more embodiments relate to a display apparatus.

### 2. Description of the Related Art

A display apparatus visually displays data. The display apparatus is utilized as a display unit of a small-screen product such as a portable phone, and is also utilized as a display unit of a large-screen product such as a television.

The display apparatus includes a plurality of pixels that emit light by receiving electrical signals to display an image externally. Each pixel includes a light-emitting element. For example, in the case of an organic light-emitting display apparatus, the pixel includes an organic light-emitting diode (OLED) as the light-emitting element. Typically, an organic light-emitting display apparatus includes thin-film transistors and organic light-emitting diodes on a substrate, and the organic light-emitting diodes emit light by themselves to operate the organic light-emitting display apparatus.

Display apparatuses are recently used in various fields, and thus, various designs for improving the quality of the display apparatuses have been attempted.

### SUMMARY

One or more embodiments of the present disclosure provide a display apparatus exhibiting improved reliability and superior display quality. However, the embodiments are examples, and the scope of the disclosure is not limited to or by the embodiments that are explicitly described.

According to one or more embodiments, a display apparatus includes a substrate, a pixel electrode arranged on the substrate, a pixel defining layer on the pixel electrode, the pixel defining layer having a first opening extending to a central portion of the pixel electrode, an intermediate layer on the pixel electrode and including an emission layer, a metal layer on the intermediate layer, the metal layer having a second opening extending to a central portion of the intermediate layer, and an opposite electrode continuously disposed on the intermediate layer and the metal layer.

In an embodiment, the pixel defining layer may include an amorphous metal material.

In an embodiment, the amorphous metal material may be an Al-based alloy.

In an embodiment, the Al-based alloy may have an atomic ratio of aluminum in a range of at least 90 at % and less than 100 at %.

In an embodiment, the Al-based alloy may include one or more of terbium (Tb), cerium (Ce), yttrium (Y), iron (Fe), and nickel (Ni).

In an embodiment, the metal layer may have a lower resistivity than the opposite electrode.

In an embodiment, at least a portion of the metal layer may overlap the pixel defining layer.

In an embodiment, the metal layer may form a closed curve along an edge of the intermediate layer in plan view.

In an embodiment, an area of the second opening may be equal to or greater than an area of the first opening.

According to another embodiment, a display apparatus includes a substrate, a first pixel electrode and a second pixel electrode spaced apart from each other on the substrate, a pixel defining layer on the first pixel electrode, the second pixel electrode, and between the first pixel electrode and the second pixel electrode, the pixel defining layer having an opening that extends to a central portion of the first pixel electrode and another opening that extends to a central portion of the second pixel electrode, a first intermediate layer on the first pixel electrode and including a first emission layer, a second intermediate layer on the second pixel electrode and including a second emission layer, a first metal layer on the first intermediate layer, the first metal layer having a first metal-layer opening extending to a central portion of the first intermediate layer, a second metal layer on the second intermediate layer, the second metal layer having a second metal-layer opening extending to a central portion of the second intermediate layer, and an opposite electrode disposed continuously on the first intermediate layer, the second intermediate layer, the first metal layer, and the second metal layer, and wherein the first metal layer and the second metal layer are spaced apart from each other.

In another embodiment, the first metal layer and the second metal layer may include the same amorphous metal material.

In another embodiment, the amorphous metal material may be an Al-based alloy.

In another embodiment, the Al-based alloy may have an atomic ratio of aluminum in a range of at least 90 at % and less than 100 at %.

In another embodiment, the Al-based alloy may include one or more of terbium (Tb), cerium (Ce), yttrium (Y), iron (Fe), and nickel (Ni).

In another embodiment, the first metal layer and the second metal layer may each have a resistivity that is lower than a resistivity of the opposite electrode.

In another embodiment, at least a portion of the first metal layer and at least a portion of the second metal layer may overlap the pixel defining layer.

In another embodiment, the first metal layer may form a closed curve along an edge of the first intermediate layer in plan view, and the second metal layer may form a closed curve along an edge of the second intermediate layer in plan view.

In another embodiment, the display apparatus may further include a spacer on the pixel defining layer and located between the first metal layer and the second metal layer.

In another embodiment, a width of the spacer may be smaller than a width of the pixel defining layer.

In another aspect, the disclosure pertains to an electronic apparatus including the above display apparatus, a memory, and a processor.

Other aspects, features, and advantages other than those described above will become apparent from the following drawings, claims, and detailed description of the disclosure.

### BRIEF DESCRIPTION OF THE DRAWINGS

FIG. 1 is a schematic plan view of a display apparatus according to one embodiment;

FIG. 2 is an equivalent circuit diagram of a pixel included in the display apparatus of FIG. 1;

FIG. 3 is a schematic cross-sectional view of an example of the display apparatus taken along the line I-I′ of FIG. 1;

FIG. 4 is a schematic plan view illustrating a portion of the display apparatus of FIG. 1;

FIG. 5 is a schematic cross-sectional view of a cross-section taken along the line II-II′ of FIG. 4;

FIG. 6 is a cross-sectional view of another example of the display apparatus taken along the line I-I′ of FIG. 1;

FIG. 7A and FIG. 7B show photographs of a surface state of a metal layer included in each of a display apparatus according to a comparative example and a display apparatus according to an embodiment;

FIG. 8 is an X-ray diffraction analysis graph of an amorphous aluminum alloy material forming a metal layer;

FIGS. 9A to 9E are schematic cross-sectional views of a method for manufacturing a display apparatus according to one embodiment;

FIGS. 10A to 10D are cross-sectional views schematically illustrating a method for manufacturing a display device according to one embodiment of the present invention; and

FIG. 11 is a block diagram of an electronic device according to an embodiment.

### DETAILED DESCRIPTION

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. The disclosure may, however, be embodied in many different forms and should not be construed as being limited to the embodiments set forth herein.

In the following embodiments, while such terms as “first,” “second,” etc., may be used to describe various elements, such elements must not be limited to the above terms.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

In the embodiments below, when various components such as layers, films, regions, and plates are said to be “above” or “on” other components, this includes not only cases where such various components are “directly above” the other components, but also cases where intervening components are present therebetween.

In the following embodiments, it will be understood that the term “connection” or “coupling” does not necessarily mean “direct and/or fixed connection or coupling” of two members, unless the context clearly indicates otherwise, and this does not preclude the arrangement of other members between the two members.

Sizes of elements in the drawings may be exaggerated for convenience of explanation. In other words, since sizes and thicknesses of components in the drawings are arbitrarily illustrated for convenience of explanation, the following embodiments are not limited thereto.

When an embodiment may be implemented differently, the order of specific steps may be performed differently from the order described. For example, two steps described in succession may be performed substantially at the same time or may be performed in a reverse order opposite to that described.

Hereinafter, embodiments will be described in detail with reference to the accompanying drawings. When describing embodiments with reference to the accompanying drawings, the same or corresponding elements are denoted by the same reference numerals, and redundant descriptions are omitted.

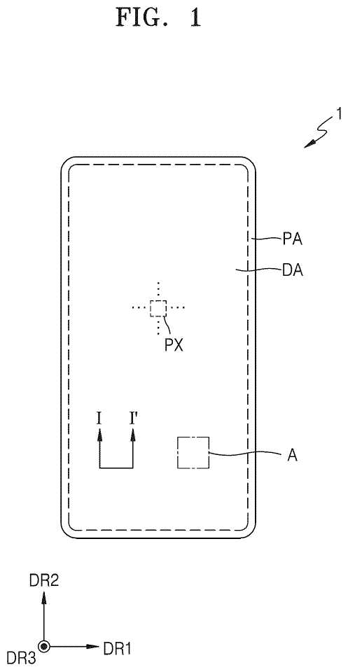

FIG. 1 is a schematic plan view of a display apparatus 1 according to one embodiment.

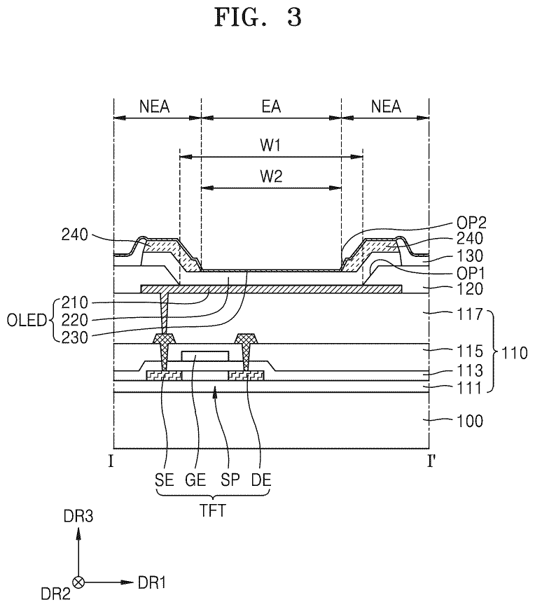

Referring to FIG. 1, the display apparatus 1 may include a display area DA in which a plurality of pixels PX are arranged and a peripheral area PA located outside the display area DA. In some embodiments, the peripheral area PA may entirely surround the display area DA. This may be understood as meaning that the substrate 100 (see FIG. 3) included in the display apparatus has the display area DA and the peripheral area PA.

Each pixel PX of the display apparatus 1 is an area that emits light of a predetermined color, and the display apparatus 1 may provide an image using light emitted from the pixels PX. The pixels P may each emit, for example, red light, green light, blue light, or white light. Each pixel PX may denote a sub-pixel and may include a display element and a pixel circuit connected to the display element. The display element may include an organic light-emitting diode or a quantum dot organic light-emitting diode.

The plurality of pixels PX may be arranged in a matrix form along a first direction DR1 and a second direction DR2. The first direction DR1 and the second direction DR2 may be defined as directions that intersect each other. Hereinafter, a third direction DR3 may be defined as a direction intersecting a plane which is defined by the first direction DR1 and the second direction DR2. A state “when viewed on a plane” or “in plan view,” as used herein, may be defined as a state viewed from the third direction DR3.

The display area DA may have a polygonal shape including a rectangle, as illustrated in FIG. 1. For example, the display area DA may have a rectangular shape that extends longer in the second direction DR2 than in the first direction DR1. Alternatively, the display area DA may have various shapes, such as an ellipse or a circle.

The peripheral area PA may be a non-display area where any pixel PX is not arranged. Drivers, etc. for providing electrical signals or power to the pixels PX may be arranged in the peripheral area PA. The peripheral area PA may include pads (not illustrated) to which various electronic components or a printed circuit board may be electrically connectable. The pads may be arranged spaced apart from each other in the peripheral area PA and may be electrically connected to the printed circuit board or integrated circuit device.

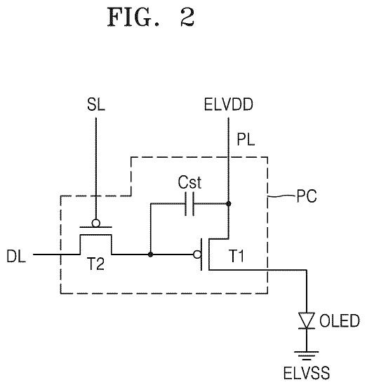

FIG. 2 is an equivalent circuit diagram of a pixel PX included in the display apparatus 1 of FIG. 1.

Referring to FIG. 2, a pixel PX may include a pixel circuit PC and an organic light-emitting diode OLED electrically connected to the pixel circuit PC.

The pixel circuit PC may include a first transistor T1, a second transistor T2, and a storage capacitor Cst. The second transistor T2 may be a switching transistor. The second transistor T2 may be connected to a scan line SL and a data line DL, and turned on by a switching signal input from the scan line SL, to transmit a data signal input from the data line DL to the first transistor T1. The storage capacitor Cst may have one end electrically connected to the second transistor T2 and another end electrically connected to a driving voltage line PL, and may store a voltage corresponding to a difference between a voltage received from the second transistor T2 and a driving power voltage ELVDD supplied to the driving voltage line PL.

The first transistor T1 that is a driving transistor may be connected to the driving voltage line PL and the storage capacitor Cst, and may control an amount of a driving current, which flows to the organic light-emitting diode OLED from the driving voltage line PL, in response to a voltage value stored in the storage capacitor Cst. The organic light-emitting diode OLED may emit light with a certain brightness depending on the driving current. An opposite electrode of the organic light-emitting diode OLED may receive an electrode power voltage ELVSS.

In FIG. 2, the case where the pixel circuit PC includes two thin-film transistors and one storage capacitor is described, but the disclosure is not limited thereto. For example, the number of transistors or the number of storage capacitors may vary depending on the design of the pixel circuit PC.

FIG. 3 is a schematic cross-sectional view of an example of the display apparatus 1 taken along the line I-I′ of FIG. 1.

Referring to FIG. 3, the display apparatus 1 according to one embodiment may include a substrate 100, a thin-film transistor TFT, an organic light-emitting diode OLED, and a metal layer 240. The thin-film transistor TFT, the organic light-emitting diode OLED, and the metal layer 240 may be arranged on the substrate 100.

The substrate 100 may include various flexible or bendable materials. For example, the substrate 100 may include glass, metal, or polymer resin. For example, the substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The configuration of the substrate 100 may, of course, vary suitably. For example, the substrate 100 may have a multi-layer structure including two layers each including the polymer resin, and a barrier layer which includes an inorganic material (e.g., silicon oxide, silicon nitride, silicon oxynitride, etc.), and is interposed between the two layers.

A buffer layer 111 may be arranged on the substrate 100. The buffer layer 111 may include an inorganic material such as silicon nitride (SiNx), silicon oxynitride (SiOxNy), silicon oxide (SiOx), etc. The buffer layer 111 may be arranged on the substrate 100 to increase flatness of an upper surface of the substrate 100 or suppress or minimize infiltration of impurities from the substrate 100, etc., to a semiconductor layer SP of the thin-film transistor TFT.

The thin-film transistor TFT may be arranged on the buffer layer 111. The thin-film transistor TFT may include a semiconductor layer SP, a gate electrode GE, a source electrode SE, and a drain electrode DE. The semiconductor layer SP may be arranged on the buffer layer 111. The semiconductor layer SP may include amorphous silicon, polycrystalline silicon, an organic semiconductor material, or an oxide semiconductor material.

A first insulating layer 113 may be arranged on the semiconductor layer SP. The first insulating layer 113 may include an inorganic material such as silicon nitride (SiNx), silicon oxynitride (SiOxNy), or silicon oxide (SiOx), and may be a single layer or a multi-layer including the above materials. The first insulating layer 113 may be interposed between the semiconductor layer SP and the gate electrode GE to secure insulation between the semiconductor layer SP and the gate electrode GE.

The gate electrode GE may be arranged on the first insulating layer 113. The gate electrode GE may include a low-resistance conductive material, such as molybdenum (Mo), aluminum (Al), copper (Cu), and/or titanium (Ti), and may be a single layer or a multi-layer including the above materials.

A second insulating layer 115 may be arranged on the gate electrode GE. The second insulating layer 115 may include an inorganic material such as silicon nitride (SiNx), silicon oxynitride (SiOxNy), or silicon oxide (SiOx), and may be a single layer or a multi-layer including the above materials.

The source electrode SE and the drain electrode DE may be arranged on the second insulating layer 115. The source electrode SE and the drain electrode DE may include at least one material selected from a group consisting of copper, titanium, and aluminum. For example, the source electrode SE and the drain electrode DE may include a three-layer structure including a titanium layer, an aluminum layer, and a titanium layer.

A planarization layer 117 may be arranged on the source electrode SE and the drain electrode DE. The planarization layer 117 may be a polyimide-based resin layer having a single-layer structure. However, the disclosure is not limited thereto. The planarization layer 117 may include at least one of an acrylic resin, a methacrylic resin, polyisoprene, a vinyl-based resin, an epoxy-based resin, a urethane-based resin, a cellulosic resin, a siloxane-based resin, a polyamide-based resin, and a perylene-based resin.

In FIG. 3, the insulating layer 110 from the buffer layer 111 to the planarization layer 117 is described, but the disclosure is not limited thereto. In another embodiment, more insulating layers may, of course, be arranged depending on the structure of the thin-film transistor TFT and the storage capacitor Cst.

The organic light-emitting diode OLED may be arranged on the planarization layer 117. The organic light-emitting diode OLED may include a pixel electrode 210, an intermediate layer 220, and an opposite electrode 230.

The pixel electrode 210 may be arranged on the planarization layer 117. The pixel electrode 210 may be electrically connected to the source electrode SE and/or the drain electrode DE through a via hole, which is defined in the planarization layer 117. Therefore, an organic light-emitting diode OLED may be electrically connected to the thin-film transistor TFT.

The pixel electrode 210 may include a conductive oxide, such as indium tin oxide (ITO), indium zinc oxide (IZO), zinc oxide (ZnO), indium oxide (In2O3), indium gallium oxide (IGO), or aluminum zinc oxide (AZO). In an embodiment, the pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 210 may further include a film formed of ITO, IZO, ZnO, or In2O3 above/below the reflective film. For example, the pixel electrode 210 may have a multi-layer structure of ITO/Ag/ITO.

A pixel defining layer 120 having a first opening OP1, which exposes a central portion of the pixel electrode 210, may be arranged on the pixel electrode 210. The pixel defining layer 120 may overlap an edge of the pixel electrode 210 when viewed from a direction (an axial direction DR3) approximately perpendicular to the substrate 100. The pixel defining layer 120 may increase a distance between the edge of the pixel electrode 210 and the opposite electrode 230 above the pixel electrode 210. This may suppress an arc and the like from being generated at the edge of the pixel electrode 210. In an embodiment, an inner surface of the pixel defining layer 120, which defines the first opening OP1, may be defined as an inclined surface forming a certain angle with an upper surface of the substrate 100.

The pixel defining layer 120 may include an inorganic insulating material such as silicon nitride (SiNx), silicon oxynitride (SiON), or silicon oxide (SiOx). In some embodiments, the pixel defining layer 120 may include a light-shielding material and may be formed as a black layer. The light-shielding material may include a resin or paste containing carbon black, carbon nanotubes, or black dye, metal particles, for example, nickel, aluminum, molybdenum, and alloys thereof, metal oxide particles (e.g., chromium oxide), or metal nitride particles (e.g., chromium nitride). When the pixel defining layer 120 includes a light-shielding material, external reflections due to metal structures arranged below the pixel defining layer 120 may be reduced.

The intermediate layer 220 including an emission layer that emits light of a certain color may be arranged on the pixel electrode 210. The intermediate layer 220 may include a low-molecular material or a high-molecular material. When the intermediate layer 220 includes a low-molecular weight material, the intermediate layer 220 may include a hole injection layer (HIL), a hole transport layer (HTL), an emission Layer (EML), an electron transport layer (ETL), and an electron injection layer (EIL), which have a single-layer structure or a multi-layered structure. The intermediate layer 220 may be formed by a vacuum deposition method. When the intermediate layer 220 includes a high-molecular material, the intermediate layer 420 may have a structure including an HTL and an EML. In this instance, the HTL may include PEDOT, and the EML may include a high-molecular weight material such as poly-phenylenevinylene (PPV)-based high-molecular material, and polyfluorene-based high-molecular material. Of course, the intermediate layer 220 is not necessarily limited thereto, and may also have various structures. The intermediate layer 220 may be formed by screen printing, inkjet printing, deposition, or laser induced thermal imaging (LITI).

In an embodiment, the intermediate layer 220 may be formed by being patterned on the pixel electrode 210. The intermediate layer 220 may be connected to the pixel electrode 210 through the first opening OP1 of the pixel defining layer 120. An edge of the intermediate layer 220 may be arranged on the pixel defining layer 120. That is, the edge of the intermediate layer 220 may overlap the pixel defining layer 120 when viewed on a plane. However, the disclosure is not limited thereto, and the intermediate layer 220 may be patterned to be arranged within the first opening OP1.

The metal layer 240 has a second opening OP2 that is aligned with the first opening OP1 and exposes a central portion of the intermediate layer 220. The metal layer 240 may be a portion remaining after removing a sacrificial layer, which protects an upper surface of the intermediate layer 220.

The metal layer 240 may be arranged along the edge of the intermediate layer 220. That is, the metal layer 240 may form a closed curve along the edge of the intermediate layer 220 to expose the central portion of the intermediate layer 220 when viewed on a plane. An outer surface of the metal layer 240 may be formed to be flush with an outer surface of the intermediate layer 220.

The metal layer 240 may overlap (or at least partially overlap) the pixel defining layer 120 when viewed on a plane. For example, a width W2 of the second opening OP2 defined in the metal layer 240 may be smaller than a width W1 of the first opening OP1 defined in the pixel defining layer 120. In this instance, the metal layer 240 may partially overlap the pixel defining layer 120. The metal layer 240 that partially overlaps the pixel defining layer 120 may be formed such that a sidewall defining the second opening OP2 is closer to the central portion of the intermediate layer 220 than a sidewall defining the first opening OP1 of the pixel defining layer 120. In this instance, the width W2 of the second opening OP2 may be the same as a width of an emission area EA.

In some embodiments, the width W2 of the second opening OP2 defined in the metal layer 240 may be equal to or bigger than the width W1 of the first opening OP1 defined in the pixel defining layer 120. In this instance, the entire metal layer 240 may overlap the pixel defining layer 120, and the width W1 of the first opening OP1 may be the same as the width of the emission area EA.

That is, the first opening OP1 defined in the pixel defining layer 120 or the second opening OP2 defined in the metal layer 240 may define the emission area EA, through which light is emitted from the organic light-emitting diode OLED. At least one of one of the first opening OP1 and the second opening OP2, whichever has a smaller width value, may be the width of the emission area EA. The periphery of the emission area EA may be a non-emission area NEA, and the non-emission area NEA may surround the emission area EA.

The metal layer 240 may be arranged between the intermediate layer 220 and the opposite electrode 230 and may serve as an auxiliary electrode of the opposite electrode 230. In some embodiments, the metal layer 240 may be formed to have a resistance lower than a resistance of a portion of the opposite electrode 230 that comes into contact with the metal layer 240, and may allow voltage to be more effectively supplied to the organic light-emitting diode OLED through the opposite electrode 230.

For example, the metal layer 240 may be made of a material having a lower resistance than the opposite electrode 230. That is, a resistivity of the metal layer 240 may be lower than a resistivity of the opposite electrode 230. However, the disclosure is not limited thereto, and the display apparatus 1 may also allow the metal layer 240 to have a lower resistance than the opposite electrode 230 by adjusting a thickness or length of the metal layer 240.. As shown, the opposite electrode 230 is disposed continuously on the intermediate layer 220, the metal layer 240, and the spacer 130 (described below).

The metal layer 240 may include a material that may selectively be etched without damaging the intermediate layer 220. In an embodiment, the metal layer 240 may include an amorphous metal material. Here, an amorphous state may mean a state having no regular crystal structure.

In a manufacturing process of the display apparatus 1 according to one embodiment, a photolithography process may be carried out after forming a sacrificial layer, which is made of an amorphous metal material, on a thin film for forming the intermediate layer. The sacrificial layer of the display apparatus 1 may be made of the amorphous metal material, thereby suppressing erosion at grain boundaries due to crystallization of the sacrificial layer. Accordingly, in the display apparatus 1, the intermediate layer 220 may be protected through a more robust sacrificial layer, the sacrificial layer may be effectively suppressed from being lost or lifted, and the reliability of the display apparatus 1 may be improved.

Meanwhile, in the manufacturing process of the display apparatus 1, the sacrificial layer may be partially left without being removed during the removal of the sacrificial layer, thereby forming the metal layer 240. The metal layer 240 may include the same amorphous metal material as the sacrificial layer. In an embodiment, the metal layer 240 may be formed of an amorphous Al-based alloy. When the metal layer 240 is made of the Al-based alloy, etching using an acid-based etchant may be facilitated, and the damage to the intermediate layer 220 due to the etchant may be suppressed.

In an embodiment, the Al-based alloy forming the metal layer 240 may include one or more of terbium (Tb), cerium (Ce), yttrium (Y), iron (Fe), and nickel (Ni). For example, the Al-based alloy forming the metal layer 240 may be one of compositions of AlTb, AlCe, AlY, AlYFe, and AlNiY4. In this instance, the Al-based alloy forming the metal layer 240 may have an atomic ratio of aluminum in the range of at least 90 at % and less than 100 at %.

In some embodiments, the sacrificial layer above the intermediate layer 220 may be completely removed so that no metal layer 240 may be present.

A spacer 130 may be arranged on the pixel defining layer 120. The pixel defining layer 120 and the spacer 130 may overlap the non-emission area NEA. The spacer 130 may cover a side surface of the intermediate layer 220 and a side surface of the metal layer 240. The spacer 130 may protrude from the pixel defining layer 120 in the third direction DR3 that is perpendicular to the substrate 100, and may protrude more upward than an upper surface of the metal layer 240. In an embodiment, the spacer 130 may include, but is not limited to, the same inorganic insulating material as the pixel defining layer 120.

The opposite electrode 230 may be arranged on the intermediate layer 220 and the metal layer 240. The opposite electrode 230 may be made of a conductive material having a relatively low work function. In an embodiment, the opposite electrode 230 may include a (semi)transparent layer that includes silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 230 may further include a layer, such as ITO, IZO, ZnO, or In2O3, on the (semi)transparent layer including the above materials.

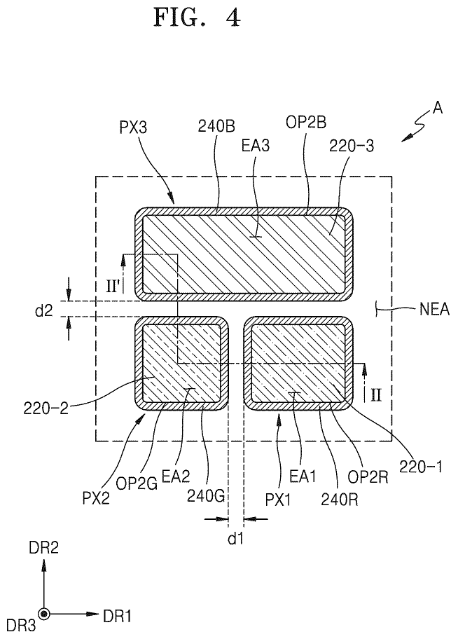

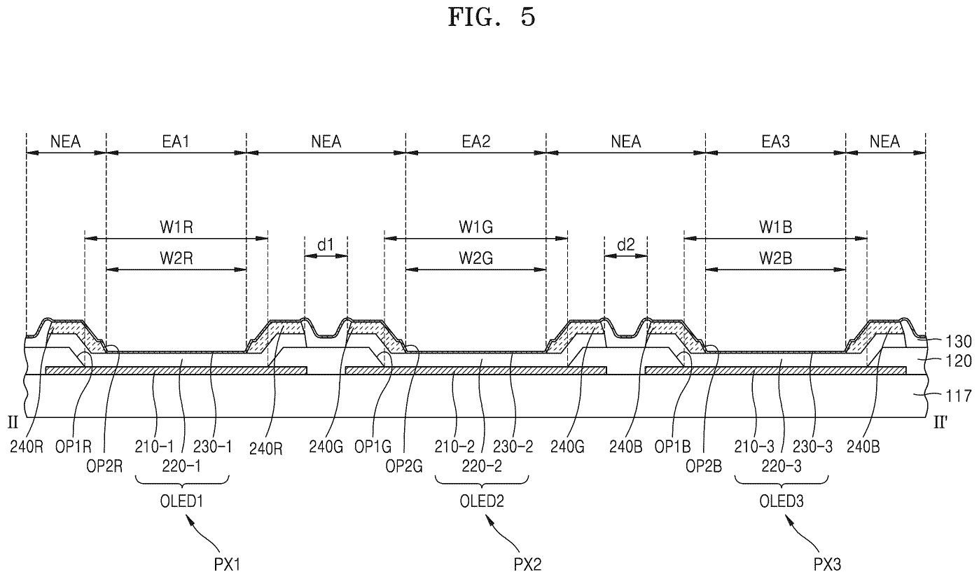

FIG. 4 is a schematic plan view illustrating a portion A of the display apparatus 1 of FIG. 1, and FIG. 5 is a schematic cross-sectional view of a cross-section taken along the line II-II′ of FIG. 4.

First, referring to FIG. 4, the display apparatus 1 may include a plurality of pixels PX1, PX2, and PX3. The pixels PX1, PX2, and PX3 may include a first pixel PX1, a second pixel PX2, and a third pixel PX3 that emit light of different colors. The first pixel PX1, the second pixel PX2, and the third pixel PX3 may each emit light having one of red, green, blue, or white color.

Each of the first pixel PX1, the second pixel PX2, and the third pixel PX3 may have a polygonal shape when viewed on a plane. In FIG. 4, each of the first pixel PX1, the second pixel PX2, and the third pixel PX3 is shown having a square shape, for example, a square shape with rounded corners, when viewed on a plane. However, the disclosure is not limited thereto. For example, each of the first pixel PX1, the second pixel PX2, and the third pixel PX3 may alternatively have a circular or elliptical shape when viewed on a plane.

The first pixel PX1, the second pixel PX2, and the third pixel PX3 may have different sizes, namely, areas, from one another. For example, the area of the second pixel PX2 may be narrower than the area of the first pixel PX1 and the area of the third pixel PX3. However, the disclosure is not limited thereto. For example, the first pixel PX1, the second pixel PX2, and the third pixel PX3 may have substantially the same area.

The first pixel PX1, the second pixel PX2, and the third pixel PX3 may be arranged in a S-Stripe manner. That is, in the first direction DR1, the first pixel PX1 and the second pixel PX2 may be positioned in an alternating manner, and in the third direction DR3, a pair of the first pixel PX1 and the second pixel PX2 alternates with the third pixel PX3. The arrangement of the first pixel PX1, the second pixel PX2, and the third pixel PX3 is not limited to what is explicitly described herein, and various arrangements such as a pentile configuration, a mosaic configuration, and a stripe configuration may all be applicable.

The first pixel PX1 may have a first metal layer 240R, the second pixel PX2 may have a second metal layer 240G, and the third pixel PX3 may have a third metal layer 240B. The first metal layer 240R may be arranged along an edge of a first intermediate layer 220-1. The first metal layer 240R may cover the edges of the first intermediate layer 220-1 and have a second-1 opening OP2R exposing a central portion of the first intermediate layer 220-1. A first emission area EA1 may be defined by the second-1 opening OP2R. The first metal layer 240R may form a closed curve surrounding the first emission area EA1 in plan view.

The second metal layer 240G may be arranged along an edge of a second intermediate layer 220-2 and may have a second-2 opening OP2G exposing a central portion of the second intermediate layer 220-2. A second emission area EA2 may be defined by the second-2 opening OP2G. The second metal layer 240G may form a closed curve surrounding the second emission area EA2 in plan view.

The third metal layer 240B may be arranged along an edge of a third intermediate layer 220-3 and may have a second-3rd opening OP2B extending to a central portion of the third intermediate layer 220-3. A third emission area EA3 may be defined by the second-3rd opening OP2B. The third metal layer 240B may form a closed curve surrounding the third emission area EA3 in plan view. The second-1 opening OP2R, the second-2 opening OP2G, and the second-3rd opening OP2B may herein be referred to as the first, second, and third “metal-layer openings,” respectively.

The first metal layer 240R, the second metal layer 240G, and the third metal layer 240B may be spaced apart from one another. As illustrated in FIG. 5, a spacer 130 may be arranged between the metal layers 240R, 240G, 240B adjacent to each other. For example, the first metal layer 240R and the second metal layer 240G may be spaced apart by a first distance d1 in the first direction DR1, and the second metal layer 240G and the third metal layer 240B may be spaced apart by a second distance d2 along the third direction DR3. In this instance, the first distance d1 and the second distance d2 may have the same value, but this is not a limitation of the disclosure.

Referring to FIG. 5, a first organic light-emitting diode OLED1 of the first pixel PX1, a second organic light-emitting diode OLED2 of the second pixel PX2, and a third organic light-emitting diode OLED3 of the third pixel PX3 may be arranged on the substrate 100 (see FIG. 3). The first organic light-emitting diode OLED1 may include a first pixel electrode 210-1, a first intermediate layer 220-1, and a first opposite electrode 230-1. The second organic light-emitting diode OLED2 may include a second pixel electrode 210-2, a second intermediate layer 220-2, and a second opposite electrode 230-2. The third organic light-emitting diode OLED3 may include a third pixel electrode 210-3, a third intermediate layer 220-3, and a third opposite electrode 230-3. The first organic light-emitting diode OLED1, the second organic light-emitting diode OLED2, and the third organic light-emitting diode OLED3 may have similar structures or the same structure.

The first pixel electrode 210-1, the second pixel electrode 210-2, and the third pixel electrode 210-3 may be arranged spaced apart from one another on the substrate 100. The first to third pixel electrodes 210-1, 210-2, and 210-3 may be formed on the same layer. For example, the first to third pixel electrodes 210-1, 210-2, and 210-3 may be formed on the planarization layer 117.

Various layers may be formed before forming the first to third pixel electrodes 210-1, 210-2, and 210-3. For example, thin-film transistors TFT and storage capacitors Cst corresponding to the first pixel PX1, the second pixel PX2, and the third pixel PX3 may be formed on the substrate 100, and the planarization layer 117 may be formed to cover the thin-film transistors TFT and the storage capacitors Cst. Afterward, the first to third pixel electrodes 210-1, 210-2, and 210-3 may be formed on the planarization layer 117.

The pixel defining layer 120 may be arranged on the first to third pixel electrodes 210-1, 210-2, and 210-3. The pixel defining layer 120 may cover the edges of the respective first to third pixel electrodes 210-1, 210-2, and 210-3. That is, the pixel defining layer 120 may include a 1-1th opening OP1R extending to a central portion of the first pixel electrode 210-1, a 1-2th opening OP1G extending to a central portion of the second pixel electrode 210-2, and a 1-3th opening OP1B extending to a central portion of the third pixel electrode 210-3. The pixel defining layer 120 may include an inorganic insulating material such as silicon nitride (SiNx), silicon oxynitride (SiON), or silicon oxide (SiOx).

The first intermediate layer 220-1 including a first emission layer may be arranged on the first pixel electrode 210-1. The first intermediate layer 220-1 may be patterned to correspond to the first pixel electrode 210-1. The edge of the first intermediate layer 220-1 may overlap the pixel defining layer 120 on a plane. The description of the first intermediate layer 220-1 may be applied to the second intermediate layer 220-2 and the third intermediate layer 220-3.

A first metal layer 240R having a first metal-layer opening OP2R extending to the central portion of the first intermediate layer 220-1 may be arranged on the first intermediate layer 220-1. The first metal layer 240R may be formed along the edges of the first intermediate layer 220-1. That is, the first metal layer 240R may cover the edges of the first intermediate layer 220-1 and may have the second-1 opening OP2R extending to the central portion of the first intermediate layer 220-1.

The first metal layer 240R may be made of a material having a lower resistance than the first opposite electrode 230-1. A resistivity value of the first metal layer 240R may be smaller than a resistivity value of the opposite electrode 230. Further, the first metal layer 240R may include an amorphous metal material and may include a material that may be selectively etched without damaging the first intermediate layer 220-1.

For example, the first metal layer 240R may be made of an amorphous Al-based alloy. In this instance, the Al-based alloy forming the metal layer 240 may have an atomic ratio of aluminum in the range of at least 90 at % and less than 100 at %. In some examples, the first metal layer 240R may be made of one of compositions of AlTb, AlCe, AlY, AlYFe, and AlNiY4. The description of the first metal layer 240R may be applied to the second metal layer 240G and the third metal layer 240B.

A width W2R of the second-1 opening OP2R disposed in the first metal layer 240R may be smaller than a width W1R of the 1-1th opening OP1R. Accordingly, the width W2R of the second-1 opening OP2R may be a width of a first emission area EA1. Likewise, a width W2G of the second-2 opening OP2G disposed in the second metal layer 240G may be a width of a second emission area EA2, and a width W2B of the second-3rd opening OP2B disposed in the third metal layer 240B may be a width of a third emission area EA3.

The first metal layer 240R, the second metal layer 240G, and the third metal layer 240B may be spaced apart from one another. As illustrated in FIG. 5, the second metal layer 240G may be spaced apart from the adjacently arranged first metal layer 240R by a first distance d1, and may be spaced apart from the adjacently arranged third metal layer 240B by a second distance d2. In this instance, the first distance d1 and the second distance d2 may be the same, but this is not a limitation of the disclosure.

Spacers 130 may be arranged in gap spaces between the second metal layer 240G and the first metal layer 240R and the third metal layer 240B, respectively. The spacers 130 may be arranged between the adjacent pixels PX1, PX2, and PX3 on the pixel defining layer 120. In some examples, the spacers 130 may be arranged between the adjacent pixels PX1, PX2, and PX3, respectively, to cover outer surfaces of the intermediate layers 220-1, 220-2, and 220-3 and outer surfaces of the metal layers 240R, 240G, and 240B.

A width of the spacer 130 may be smaller than the width of the pixel defining layer 120. Here, the width of the spacer 130 and the width of the pixel defining layer 120 may refer to a distance in the first direction DR1 or the second direction DR2, which intersects the third direction DR3, in a cross-section of the display apparatus 1 cut in the third direction DR3 perpendicular to the substrate 100.

For example, the spacer 130 may include an inorganic insulating material such as silicon nitride (SiNx), silicon oxynitride (SiON), or silicon oxide (SiOx), but is not limited thereto, and may also include an organic insulating material such as polyimide. The spacer 130 may include the same material as or a different material from the pixel defining layer 120.

The first opposite electrode 230-1 may be arranged on the first intermediate layer 220-1 and the first metal layer 240R. The second opposite electrode 230-2 may be arranged on the second intermediate layer 220-2 and the second metal layer 240G. The third opposite electrode 230-3 may be arranged on the third intermediate layer 220-3 and the third metal layer 240B.

The first opposite electrode 230-1, the second opposite electrode 230-2, and the third opposite electrode 230-3 may be formed of the same material simultaneously through the same process. In some examples, the material forming the first opposite electrode 230-1, the second opposite electrode 230-2, and the third opposite electrode 230-3 may be deposited on the entire surface of the substrate 100.

That is, the opposite electrodes included in a plurality of display elements may be formed as a single body over the entire surface of the display area DA, and may be electrically connected. The same electrical signal may be applied to the plurality of display elements through the opposite electrodes formed as the single body. For example, the same electrode power voltage ELVSS may be applied to the plurality of display elements through the opposite electrodes formed as the single body. Therefore, the opposite electrodes formed as the single body may serve as wirings for applying the electrode power voltage ELVSS to the display elements.

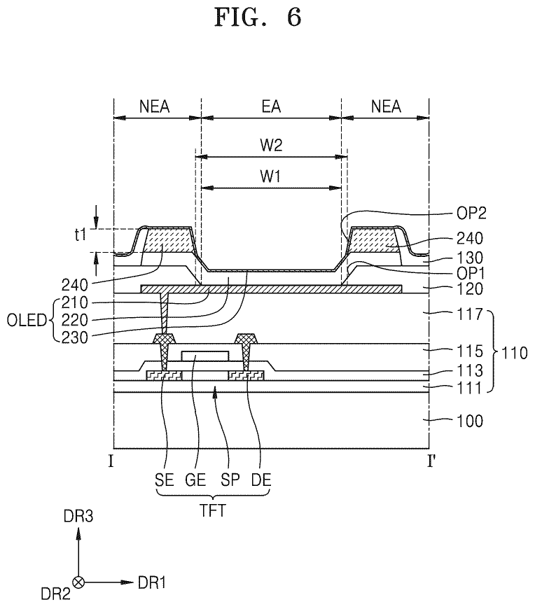

FIG. 6 is a cross-sectional view of another example of the display apparatus 1 taken along the line I-I′ of FIG. 1. The display apparatus 1 of FIG. 6 may have a difference in the structure of the metal layer 240, compared to the display apparatus 1 of FIG. 3. Hereinafter, a description will be given focusing on the difference between the embodiments of FIG. 3 and FIG. 6 while using the same reference numerals as defined in FIG. 3. Any redundant explanation will be omitted.

Referring to FIG. 6, the display apparatus 1 may include a metal layer 240 disposed between an intermediate layer 220 and an opposite electrode 230. The metal layer 240 may be a portion remaining after removing a sacrificial layer, which protects an upper surface of the intermediate layer 220. The metal layer 240 may be arranged along an edge of the intermediate layer 220. In some examples, the metal layer 240 may cover the edge of the intermediate layer 220 and have an opening that extends to a central portion of the intermediate layer 220. The metal layer 240 may include a second opening OP2 in its central portion.

The metal layer 240 may overlap the pixel defining layer 120 when viewed on a plane. That is, a width W2 of the second opening OP2 defined in the metal layer 240 may be greater than a width W1 of a first opening OP1 defined in a pixel defining layer 120. Since the metal layer 240 overlaps the pixel defining layer 120, an emission area EA may be defined by the first opening OP1 of the pixel defining layer 120.

The metal layer 240 according to the embodiment of FIG. 6 may have a width (i.e., a distance extending from an outer edge toward a center of the intermediate layer 220 on the intermediate layer 220), which is smaller than the width of the metal layer 240 of the display apparatus 1 described in FIG. 3. The metal layer 240 may be thinner when the metal layer 240 overlaps a greater portion of the pixel defining layer 120. In the case of FIG. 6, the metal layer 240 may be formed to have a thick thickness t1 to reduce a resistance due to the metal layer 240 itself.

That is, the thickness t1 of the metal layer 240 may vary depending on the design. When the metal layer 240 covers a smaller portion of the pixel defining layer 120, the thickness t1 of the metal layer 240 may be adjusted, thereby reducing the resistance of the metal layer 240. The display apparatus 1 may adjust the thickness of the metal layer 240 by varying a thickness of the sacrificial layer on the intermediate layer 220, and may change the length of the metal layer 240 by varying an area removed from the sacrificial layer. The display apparatus 1 may include the metal layer 240 having appropriate length and thickness, so that the metal layer 240 may effectively serve as an auxiliary electrode of the opposite electrode 230.

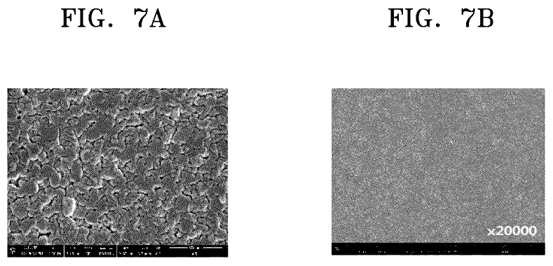

FIG. 7A shows a result obtained by photographing a surface state of a crystalline sacrificial layer, and FIG. 7B shows a result obtained by photographing a surface state of an amorphous sacrificial layer. In some examples, FIG. 7A shows the result of using a sacrificial layer made of a crystalline aluminum single-metal, and FIG. 7B shows the result of using a sacrificial layer made of an amorphous aluminum alloy corresponding to the metal layer 240 according to an embodiment.

As shown in FIG. 7A, it may be seen that the surface of the crystalline sacrificial layer becomes rough due to erosion of the sacrificial layer at grain boundaries according to a crystal structure. The erosion at the grain boundaries may cause the sacrificial layer to be lifted or lost, thereby damaging the intermediate layer 220.

In contrast, as shown in FIG. 7B, it may be seen that the amorphous sacrificial layer has a smooth surface because the amorphous sacrificial layer does not experience grain growth in the subsequent process and thereby erosion at grain boundaries does not occur. Therefore, in the display apparatus 1 using the amorphous sacrificial layer, the damage to the intermediate layer 220 may be suppressed and manufacturing efficiency may be increased.

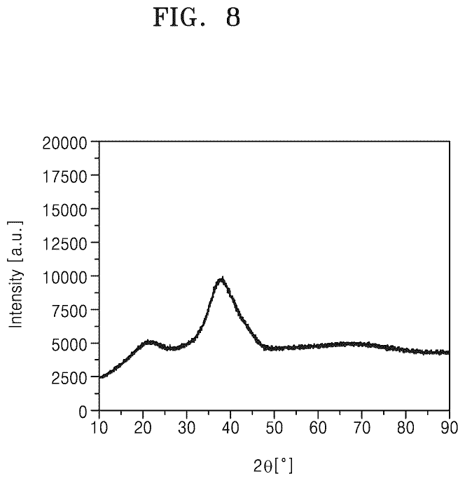

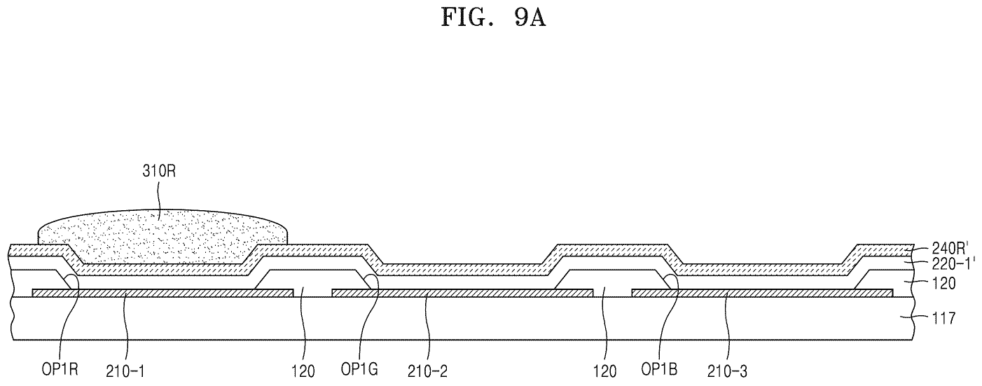

FIG. 8 is an X-ray diffraction analysis graph of an amorphous aluminum alloy material forming the metal layer 240. In some examples, FIG. 8 is a graph obtained by XRD analysis of an aluminum alloy specimen, in which an atomic ratio of aluminum has a value selected in a range of at least 90 at % to less than 100 at % and which includes nickel (Ni) and yttrium (Y).

Referring to FIG. 8, it may be confirmed that the aluminum alloy, in which the atomic ratio of aluminum has the value selected in the range of at least 90 at % to less than 100 at % and which includes nickel (Ni) and yttrium (Y), does not exhibit a crystal peak. Therefore, when forming a sacrificial layer using the aluminum alloy having the above composition, the sacrificial layer may be formed as an amorphous metal layer. Since the sacrificial layer is formed as the amorphous metal layer, erosion of the sacrificial layer due to grain boundaries may be suppressed, and the reliability of the display apparatus 1 may be improved.

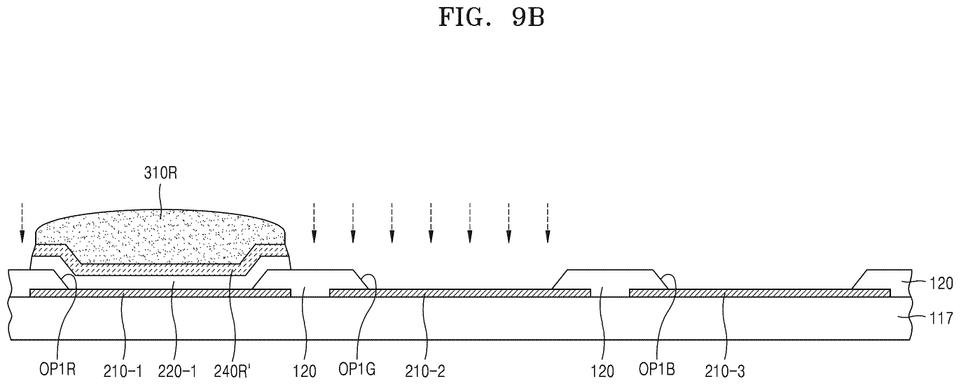

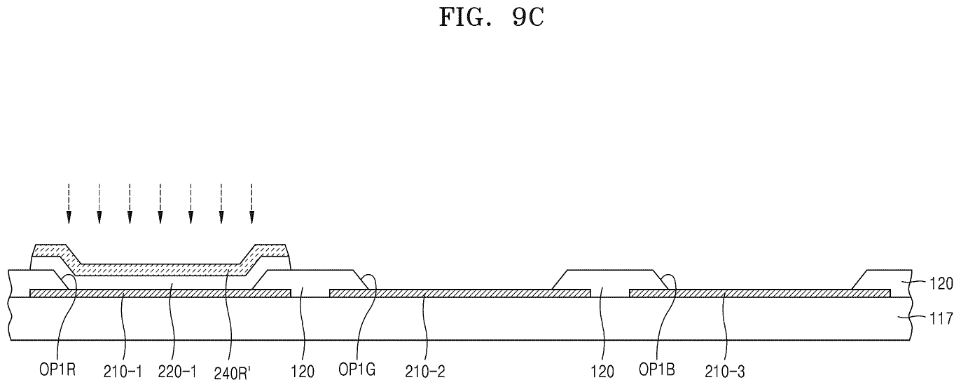

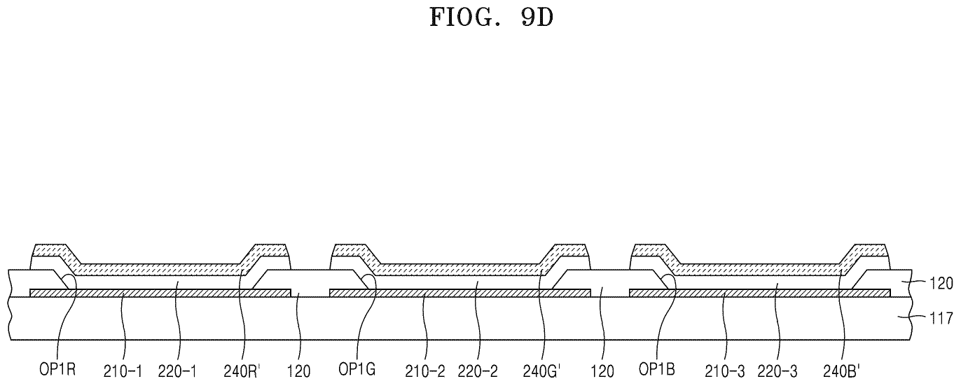

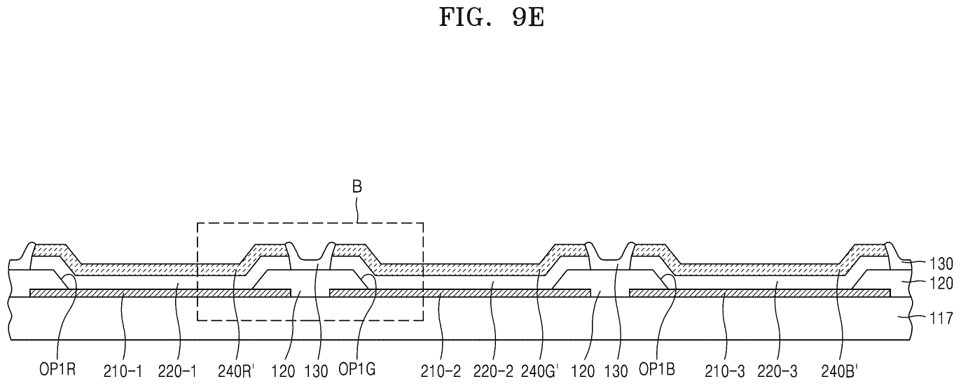

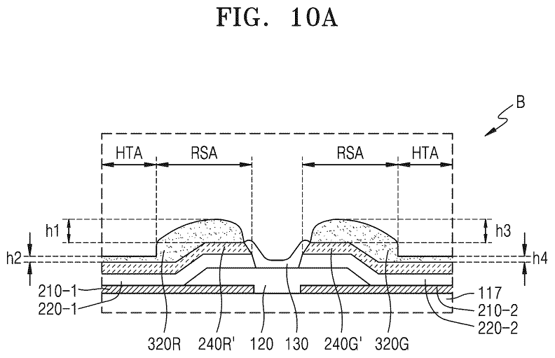

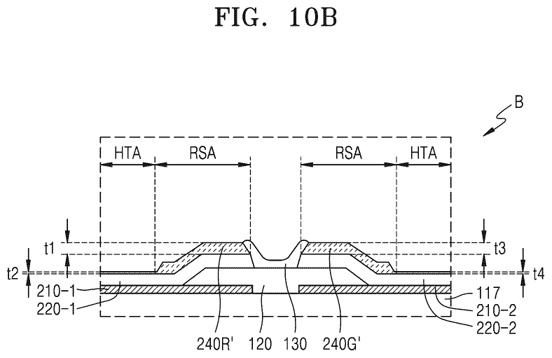

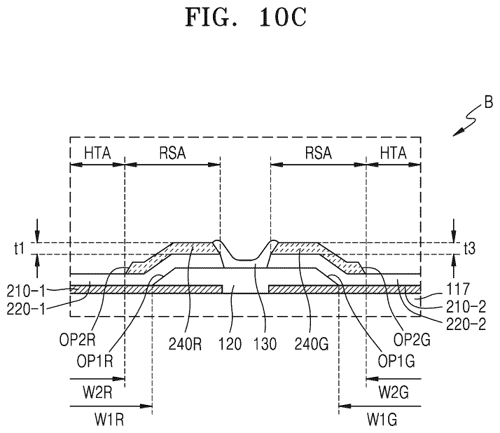

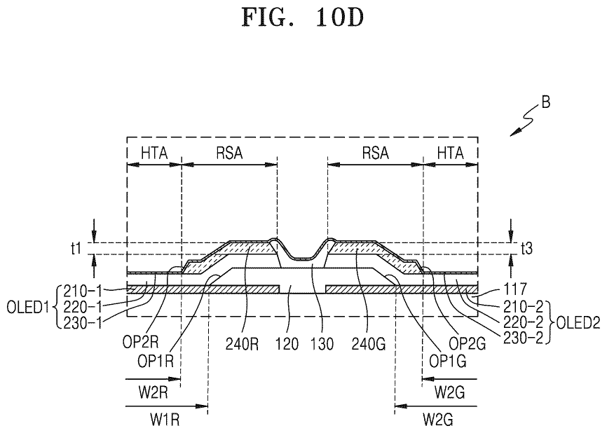

FIGS. 9A to 10D are schematic cross-sectional views of a method for manufacturing a display apparatus 1 according to one embodiment. FIGS. 9A to 9E illustrate each step of the manufacturing method in areas corresponding to the areas shown in FIG. 5, and FIGS. 10A to 10D illustrate an enlarged portion B of FIG. 9E to explain a manufacturing process of a metal layer 240 in more detail.

Referring to FIG. 9A, a first pixel electrode 210-1, a second pixel electrode 210-2, and a third pixel electrode 210-3 may be disposed on a substrate 100 (see FIG. 5). Before forming the first pixel electrode 210-1, the second pixel electrode 210-2, and the third pixel electrode 210-3 on the substrate 100, a process of disposing thin-film transistors TFT and storage capacitors Cst on the substrate 100 to form a first pixel PX1, a second pixel PX2, and a third pixel PX3 and disposing a planarization layer 117 on the first pixel PX1, the second pixel PX2, and the third pixel PX3 may be performed.

The first pixel electrode 210-1, the second pixel electrode 210-2, and the third pixel electrode 210-3 may be formed on the planarization layer 117. The first pixel electrode 210-1, the second pixel electrode 210-2, and the third pixel electrode 210-3 may be formed on the planarization layer 117 spaced apart from one another.

Next, a pixel defining layer 120 may be formed on the first pixel electrode 210-1, the second pixel electrode 210-2, and the third pixel electrode 210-3. A 1-1th opening OP1R exposing a central portion of the first pixel electrode 210-1, a 1-2th opening OP1G exposing a central portion of the second pixel electrode 210-2, and a 1-3th opening OP1B exposing a central portion of the third pixel electrode 210-3 may be formed in the pixel defining layer 120. The 1-1th opening OP1R, the 1-2th opening OP1G, and the 1-3th opening OP1B may be formed by an etching process.

The pixel defining layer 120 may be formed to cover edges of the first pixel electrode 210-1, the second pixel electrode 210-2, and the third pixel electrode 210-3. The pixel defining layer 120 may include an inorganic insulating material such as silicon nitride (SiNx), silicon oxynitride (SiON), or silicon oxide (SiOx).

As shown in FIG. 9A, a first intermediate film 220-1′ may be formed to cover the first pixel electrode 210-1, second pixel electrode 210-2, third pixel electrode 210-3, and pixel defining layer 120, and a first metal film 240R′ may be formed on the first intermediate film 220-1′. The first intermediate film 220-1′and the first metal film 240R′ may be formed by various film-forming methods, such as sputtering, CVD, vacuum deposition, and pulsed laser deposition (PLD), ALD, etc.

The first metal film 240R′ may be formed using a film, which has a high resistance to an etching treatment of a film of the first intermediate film 220-1′, i.e., a material having a high etching selectivity. Further, the first metal film 240R′ may be formed using a material that may be removed by a wet etching method, which causes little damage to the first intermediate film 220-1′.

For example, an amorphous metal material may be used to form the first metal film 240R′. In particular, an amorphous Al-based alloy, which has a high resistance to an acid-based etchant, may preferably be used as the material of the first metal film 240R′. The first metal film 240R′ may be formed of an Al-based alloy material including at least one of terbium (Tb), cerium (Ce), yttrium (Y), iron (Fe), and nickel (Ni), and the atomic ratio of aluminum may be at least 90 at % and less than 100 at %.

Next, a first photoresist pattern 310R may be formed on the first metal film 240R′. The first photoresist pattern 310R may be formed on an area where the first pixel electrode 210-1 is arranged. The first photoresist pattern 310R may be formed by a photolithography process.

Referring to FIG. 9B, the first intermediate film 220-1′and the first metal film 240R′ may be etched using the first photoresist pattern 310R. For example, the process of etching the first intermediate film 220-1′and the first metal film 240R′ may involve a dry etching process, but this is not a limitation of the disclosure. By using the first photoresist pattern 310R, the first intermediate film 220-1′may be etched to form a first intermediate layer 220-1 and the first metal film 240R′ may be etched to form a first metal pattern 240R′.

Referring to FIG. 9C, after completely etching the first intermediate film 220-1′and the first metal film 240R′, the first photoresist pattern 310R may be removed. The first photoresist pattern 310R may be removed by an ashing process. In the process of etching the first intermediate film 220-1′and the ashing process of removing the first photoresist pattern 310R, an upper portion of the first intermediate film 220-1′may be protected by the first metal film 240R′ and may not be damaged.

Referring to FIG. 9D, the processes of FIGS. 9A to 9C may be repeated to form a second intermediate layer 220-2 and a second metal pattern 240G′, and again to form a third intermediate layer 220-3 and a third metal pattern 240B′.

Referring to FIG. 9E, spacers 130 may be formed on the pixel defining layer 120. The spacers 130 may be formed by an etching process using a photoresist pattern. The spacers 130 may be formed to cover a side surface of the first intermediate layer 220-1, a side surface of the first metal pattern 240R′, a side surface of the second intermediate layer 220-2, a side surface of the second metal pattern 240G′, a side surface of the third intermediate layer 220-3, and a side surface of the third metal pattern 240B′. A width of the spacer 130 may be smaller than a width of the pixel defining layer 120. The spacers 130 may include an inorganic insulating material such as silicon nitride (SiNx), silicon oxynitride (SiON), or silicon oxide (SiOx).

Referring to FIG. 10A, a second-1 photoresist pattern 320R may be formed on the first metal pattern 240R′, and a second-2 photoresist pattern 320G may be formed on the second metal pattern 240G′. The second-1 photoresist pattern 320R may be formed to have different thicknesses in a first area RSA and a second area HTA. The first area RSA may be an area where the first metal pattern 240R′ is partially left to form the first metal layer 240R, and the second area HTA may be an area where more of the first metal pattern 240R′ is removed. The second-1 photoresist pattern 320R may be formed so that a thickness h1 thereof in the first area RSA is thicker than a thickness h2 in the second area HTA. The second-1 photoresist pattern 320R having the different thicknesses in the first area RSA and the second area HTA may be formed by a photolithography process using a halftone mask.

The second-2 photoresist pattern 320G may also be formed to have different thicknesses in the first area RSA and the second area HTA, and a thickness h3 of the second-2 photoresist pattern 320G in the first area RSA may be thicker than a thickness h4 in the second area HTA.

In some examples, the thickness h1 of the second-1 photoresist pattern 320R in the first area RSA and the thickness h3 of the second-2 photoresist pattern 320G in the first area RSA may be the same, but this is not a limitation of the inventive concept, and may alternatively be different from each other. Further, the thickness h2 of the second-1 photoresist pattern 320R in the second area HTA and the thickness h4 of the second-2 photoresist pattern 320G in the second area HTA may be the same as or different from each other.

Referring to FIG. 10B, the first metal pattern 240R′ may be etched using the second-1 photoresist pattern 320R, and the second metal pattern 240G′ may be etched using the second-2 photoresist pattern 320G. The process of etching the first metal pattern 240R′ and the second metal pattern 240G′ using the second-1 photoresist pattern 320R and the second-2 photoresist pattern 320G may be a dry etching process, but this is not a limitation of the inventive concept.

The first metal pattern 240R′ etched with the second-1 photoresist pattern 320R may have different thicknesses in the first area RSA and the second area HTA. For example, the first metal pattern 240R′ may be formed such that a thickness t1 in the first area RSA is thicker than a thickness t2 in the second area HTA.

Likewise, the second metal pattern 240G′ etched with the second-2 photoresist pattern 320G may have different thicknesses in the first area RSA and the second area HTA. For example, the second metal pattern 240G′ may be formed such that a thickness t3 of a portion in the first area RSA is thicker than a thickness t4 of a portion in the second area HTA.

Meanwhile, the thickness t1 of the first metal pattern 240R′ in the first area RSA and the thickness t3 of the second metal pattern 240G′ in the first area RSA may be the same, but are not limited to being the same, and may be different from each other. Further, the thickness t2 of the first metal pattern 240R′ in the second area HTA and the thickness t4 of the second metal pattern 240G′ in the second area HTA may be the same as or different from each other.

Next, the second-1 photoresist pattern 320R and the second-2 photoresist pattern 320G may be removed. The second-1 photoresist pattern 320R and the second-2 photoresist pattern 320G may be removed by an ashing process. During the process, the first metal pattern 240R′ may protect the first intermediate layer 220-1, and the second metal pattern 240G′ may protect the second intermediate layer 220-2.

Referring to FIG. 10B and FIG. 10C, the first metal pattern 240R′ and the second metal pattern 240G′ located on the second area HTA (shown in FIG. 10B) may be removed, resulting in the structure of FIG., 10C. The process of removing the first metal pattern 240R′ and the second metal pattern 240G′ located on the second area HTA may be a wet etching process, but this is not a limitation of the inventive concept.

The portion of the first metal pattern 240R′ corresponding to the second area HTA may be removed to form a first metal layer 240R. The portion of the second metal pattern 240G′ corresponding to the second area HTA may be removed to form the second metal layer 240G. In this instance, the thickness t1 of the first metal layer 240R and the thickness t3 of the second metal layer 240G may be the same, or may be different from each other.

Further, a width W2R of a second-1 opening OP2R defined by the first metal layer 240R may be determined by the size (e.g., area) of the first metal pattern 240R′ that is removed from the second area HTA. The width W2R of the second-1 opening OP2R may be smaller than a width W1R of the 1-1th opening OP1R formed in the pixel defining layer 120, but is not limited thereto.

Likewise, a width W2G of a second-2 opening OP2G defined by the second metal layer 240G may be determined by the size (e.g., area) of the second metal pattern 240G′ removed from the second area HTA. The width W2G of the second-2 opening OP2G may be smaller than a width W1G of the 1-2th opening OP1G formed in the pixel defining layer 120, but this is not a limitation of the inventive concept.

Referring to FIG. 10D, a first opposite electrode 230-1 may be formed on the first intermediate layer 220-1 and the first metal layer 240R, and the first pixel electrode 210-1, the first intermediate layer 220-1, and the first opposite electrode 230-1 may form a first organic light-emitting diode OLED1. A second opposite electrode 230-2 may also be formed on the second intermediate layer 220-2 and the second metal layer 240G, and the second pixel electrode 210-2, the second intermediate layer 220-2, and the second opposite electrode 230-2 may form a second organic light-emitting diode OLED2.

The first opposite electrode 230-1 and the second opposite electrode 230-2 may be connected to each other and integrated with each other. The first opposite electrode 230-1 and the second opposite electrode 230-2 may be formed by a deposition method such as thermal deposition or sputtering.

The display apparatus 1 according to the embodiments may not require a fine metal mask in the process of forming the organic light-emitting diode OLED. Therefore, the display apparatus 1 may be easily implemented as a large-scale display apparatus and realize high resolution.

As described above, in the display apparatus 1 according to the embodiments, the sacrificial layer that protects the intermediate layer 220 may be made of the amorphous metal material, for example, the amorphous aluminum alloy, thereby suppressing an occurrence of erosion of the sacrificial layer at grain boundaries. In the display apparatus 1 according to the embodiments, the metal layer 240 may be formed to surround the edge of the intermediate layer 220, thereby achieving improved electrical characteristics.

In one or more embodiments, a display apparatus with improved reliability and superior display quality may be implemented by arranging a metal layer between an intermediate layer and an opposite electrode.

However, the effects of the disclosure are not limited to the above effects, and may be expanded in various ways without departing from the technical idea and scope of the disclosure.

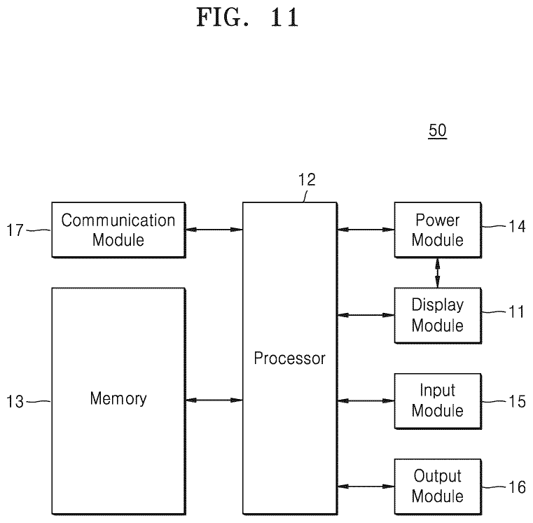

FIG. 11 is a block diagram of an electronic device according to one embodiment. Referring to FIG. 11, the electronic device 50 according to one embodiment may include a display module 11, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 11. The power module 14 may include a power supply module such as a power adapter or a battery device, and a power conversion module that converts the power supplied by the power supply module to generate power required for the operation of the electronic device 50. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 50 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 1100, and the processor 12, memory 13, and power module 14 may be provided in the form of other devices within the electronic device 11 other than the display device. The electronic device 50 may be a smartphone, a tablet, a laptop, a television, a desk monitor, a dashboard of a vehicle, a mirror, or a headmount device, among other possibilities.

Each of the embodiments described above may be implemented independently. Features from different embodiments may be combined to form other embodiments.

The disclosure is described with reference to the embodiments illustrated in the drawings, which are just examples. It will be understood by those of ordinary skill in the art that various modifications and equivalents may be made therefrom. Therefore, the true technical scope of the disclosure should be defined by the technical idea of the appended claims.

Specific implementations described are possible embodiments, and do not limit the scope of the embodiments. In addition, when there is no specific mention such as “essential,” “important,”etc., it may not be a necessary component for the application of the disclosure.

The use of the term “the” and similar demonstratives in the specification of the embodiments (in particular, the claims) is to be construed to cover both the singular and the plural. In addition, when a range is described in the embodiments, it includes the inventiive concept to which individual values within the range are applied (unless otherwise indicated herein). This is the same as stating each individual value constituting the above range in the detailed description. Finally, operations constituting methods according to embodiments may be performed in any suitable order unless otherwise indicated herein or otherwise clearly contradicted by context. The embodiments are not necessarily limited by the order of description of operations. The use of any and all examples or exemplary terms provided in the embodiments is simply intended to describe the embodiments in detail, and the scope of the embodiments is not limited by the examples or exemplary terms unless otherwise claimed. Further, it will be understood by those of ordinary skill in the art that various modifications, combinations, and changes may be made according to design conditions and factors within the scope of the appended claims or equivalents thereof.

What is claimed is:

1. A display apparatus comprising:
a substrate;
a pixel electrode arranged on the substrate;
a pixel defining layer on the pixel electrode, the pixel defining layer having a first opening extending to a central portion of the pixel electrode;
an intermediate layer on the pixel electrode and comprising an emission layer;
a metal layer on the intermediate layer, the metal layer having a second opening extending to a central portion of the intermediate layer; and
an opposite electrode on the intermediate layer and the metal layer.

2. The display apparatus of claim 1, wherein
the metal layer comprises an amorphous metal material.

3. The display apparatus of claim 2, wherein
the amorphous metal material is an aluminum (Al)-based alloy.

4. The display apparatus of claim 3, wherein
the Al-based alloy has an atomic ratio of aluminum in a range of at least 90 at % and less than 100 at %.

5. The display apparatus of claim 3, wherein
the Al-based alloy comprises one or more of terbium (Tb), cerium (Ce), yttrium (Y), iron (Fe), and nickel (Ni).

6. The display apparatus of claim 1, wherein
the metal layer has a lower resistivity than the opposite electrode.

7. The display apparatus of claim 1, wherein
at least a portion of the metal layer overlaps the pixel defining layer.

8. The display apparatus of claim 1, wherein
the metal layer forms a closed curve along an edge of the intermediate layer in plan view.

9. The display apparatus of claim 1, wherein
an area of the second opening is equal to or greater than an area of the first opening.

10. A display apparatus comprising:
a substrate;
a first pixel electrode and a second pixel electrode spaced apart from each other on the substrate;
a pixel defining layer on the first pixel electrode, the second pixel electrode, and between the first pixel electrode and the second pixel electrode, the pixel defining layer having an opening that extends to a central portion of the first pixel electrode and another opening that extends to a central portion of the second pixel electrode;
a first intermediate layer on the first pixel electrode and comprising a first emission layer;
a second intermediate layer on the second pixel electrode and comprising a second emission layer;
a first metal layer on the first intermediate layer, the first metal layer having a first metal-layer opening extending to a central portion of the first intermediate layer;
a second metal layer on the second intermediate layer, the second metal layer having a second metal-layer opening extending to a central portion of the second intermediate layer; and
an opposite electrode on the first intermediate layer, the second intermediate layer, the first metal layer, and the second metal layer, and
wherein the first metal layer and the second metal layer are spaced apart from each other.

11. The display apparatus of claim 10, wherein
the first metal layer and the second metal layer comprise a same amorphous metal material.

12. The display apparatus of claim 11, wherein
the amorphous metal material is an aluminum (Al)-based alloy.

13. The display apparatus of claim 12, wherein
the Al-based alloy has an atomic ratio of aluminum in a range of at least 90 at % and less than 100 at %.

14. The display apparatus of claim 12, wherein
the Al-based alloy comprises one or more of terbium (Tb), cerium (Ce), yttrium (Y), iron (Fe), and nickel (Ni).

15. The display apparatus of claim 10, wherein
the first metal layer and the second metal layer each have a resisivity that is lower than a resistivity of the opposite electrode.

16. The display apparatus of claim 10, wherein
at least a portion of the first metal layer and at least a portion of the second metal layer overlap the pixel defining layer.

17. The display apparatus of claim 10, wherein
the first metal layer forms a closed curve along an edge of the first intermediate layer in plan view, and
the second metal layer forms a closed curve along an edge of the second intermediate layer in plan view.

18. The display apparatus of claim 10, further comprising:
a spacer on the pixel defining layer between the first metal layer and the second metal layer.

19. The display apparatus of claim 18, wherein
a width of the spacer is smaller than a width of the pixel defining layer.

20. An electronic apparatus comprising:
a memory;
a processor executing an application stored in the memory; and
a display apparatus that comprises:
a substrate;
a pixel electrode arranged on the substrate;
a pixel defining layer on the pixel electrode, the pixel defining layer having a first opening extending to expose a central portion of the pixel electrode;
an intermediate layer on the pixel electrode and comprising an emission layer;
a metal layer on the intermediate layer, the metal layer having a second opening extending to a central portion of the intermediate layer; and
an opposite electrode on the intermediate layer and the metal layer.
